(19) United States
(12) Patent Application Publication
(10) Pub. No.: US 2024/0124971 A1
(43) Pub. Date: Apr. 18, 2024

(54) VAPORIZATION DEVICE, SEMICONDUCTOR MANUFACTURING SYSTEM, AND METHOD FOR VAPORIZING SOLID RAW MATERIAL

(71) Applicant: Tokyo Electron Limited, Tokyo (JP)

(72) Inventors: Yuichi FURUYA, Yamanashi (JP); Ryuta MOCHIZUKI, Yamanashi (JP)

(21) Appl. No.: 18/378,932

(22) Filed: Oct. 11, 2023

(30) Foreign Application Priority Data
Oct. 14, 2022 (JP) 2022-165171

(51) Int. Cl. C23C 16/448; C23C 16/44; C23C 16/455

(52) U.S. Cl. CPC C23C 16/448; C23C 16/4412; C23C 16/45565

(57) ABSTRACT

A vaporization device includes a vaporization amount adjusting plate that covers a surface of a solid raw material, and an exhaust passage that exhausts a carrier gas that flows while being faced with the vaporization amount adjusting plate. The vaporization amount adjusting plate has a plurality of through holes. An aperture ratio per unit area in the adjusting plate varies along a flowing direction of the carrier gas. The carrier gas is vaporized from the solid raw material and carries a predetermined raw material that has passed through the plurality of through holes.

### CROSS-REFERENCE TO RELATED APPLICATIONS

This application is based on and claims priority from Japanese Patent Application No. 2022-165171 filed on Oct. 14, 2022, with the Japan Patent Office, the disclosure of which is incorporated herein in its entirety by reference.

### TECHNICAL FIELD

The present disclosure relates to a vaporization device, a semiconductor manufacturing system, and a method for vaporizing a solid raw material.

### BACKGROUND

In the multilayer structure of a semiconductor device, for example, an interlayer insulating film with a low dielectric constant (low-k insulating film) and a conductive film made of copper (Cu) are stacked in some cases. In this case, a barrier layer is provided between the low-k insulating film and the conductive film in order to prevent Cu from diffusing into the low-k insulating film. Tantalum (Ta) was used in the past as a material for forming the barrier layer, but ruthenium (Ru) has been recently used because of its good adhesion to Cu.

For example, in a thermal chemical vapor deposition (TCVD), a barrier layer made of Ru is produced by thermally decomposing a solid raw material containing Ru, such as dodecacarbonyl triruthenium (DCR), and then depositing the Ru in the thermally decomposed DCR on a wafer. A multi-tray type vaporization device is used for the thermal decomposition of the DCR.

A multi-tray type vaporization device includes a cylindrical main body, a plurality of trays, which are ring-shaped containers accommodated inside the main body and stacked in the direction of the central axis, and an exhaust formed along the central axis. Each tray is filled with DCR as a solid raw material. When the DCR is thermally decomposed, each tray is heated, and the carrier gas flows from the outer peripheral side of the main body toward the exhaust passage side in the central portion. When the carrier gas flows above the DCR filled in each tray, the carrier gas entrains the vaporized DCR, passes through the exhaust passage, and flows into the processing container that accommodates the wafer (see, e.g., Japanese Patent Laid-Open Publication No. 2008-522029).

### SUMMARY

According to an embodiment of the present disclosure, a vaporization device includes a vaporization amount adjusting plate that covers a surface of a solid raw material; and an exhaust passage that exhausts a carrier gas that flows facing the vaporization amount adjusting plate. The vaporization amount adjusting plate has a plurality of through holes. An aperture ratio per unit area in the vaporization amount adjusting plate varies along a flowing direction of the carrier gas. The carrier gas is vaporized from the solid raw material and carries a predetermined raw material that has passed through the plurality of through holes.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram schematically illustrating the configuration of a semiconductor manufacturing system as an embodiment of the technology according to the present disclosure.

FIGS. 2A and 2B are diagrams illustrating the configuration of the vaporization apparatus in FIG. 1.

FIGS. 3A to 3E are diagrams illustrating remaining forms of DCR in each tray of a vaporization device of the related art.

FIGS. 4A and 4B are diagrams illustrating the progress of vaporization from DCR on the outer wall side of each tray in the vaporization device of the related art.

FIG. 5 is a diagram illustrating comparison of a graph indicating calculation results of the change in DCR concentration of a carrier gas in the relate art with a cross section of a tray.

FIG. 6 is a perspective view illustrating the configuration of a vaporization amount adjusting plate used in each tray of the vaporization device as an embodiment of the technology according to the present disclosure.

FIG. 7 is a diagram illustrating comparison of a graph indicating calculation results of the change in DCR concentration of a carrier gas when using a vaporization amount adjusting plate with a cross section of a tray.

FIGS. 8A and 8C are process diagrams illustrating how the vaporization amount adjusting plate descends as the vaporization of DCR progresses.

FIGS. 9A and 9B are perspective views illustrating a first modified embodiment of the vaporization amount adjusting plate.

FIG. 10 is a plan view illustrating the configuration of a second modified example of the vaporization amount adjusting plate.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the multi-tray type vaporization device described in Japanese Patent Laid-Open Publication No. 2008-522029, there is a tendency that in the thermal decomposition of dodecacarbonyl triruthenium (DCR), the DCR in each tray decreases from the outer peripheral side of the main body, and during the formation of the barrier layer made of Ru, all the DCR on the outer peripheral side in each tray is vaporized, so that the bottom is exposed. In this case, in each tray, the DCR remains biased towards the exhaust passage side, and, as a result, the surface area of the DCR exposed to the carrier gas is reduced. Therefore, the vaporized DCR entrained by the carrier gas decreases, and the partial pressure of the DCR in the carrier gas decreases, so that the formation efficiency of the barrier layer decreases during the process.

Accordingly, the technology according to the present disclosure reduces the DCR substantially uniformly from the outer circumferential side to the exhaust passage side in each tray, suppresses the occurrence of biasing in the DCR, and maintains the surface area of the DCR exposed to the carrier gas. Therefore, the partial pressure of the DCR in the carrier gas is prevented from decreasing, and the formation efficiency of the barrier layer is suppressed from decreasing during the process.

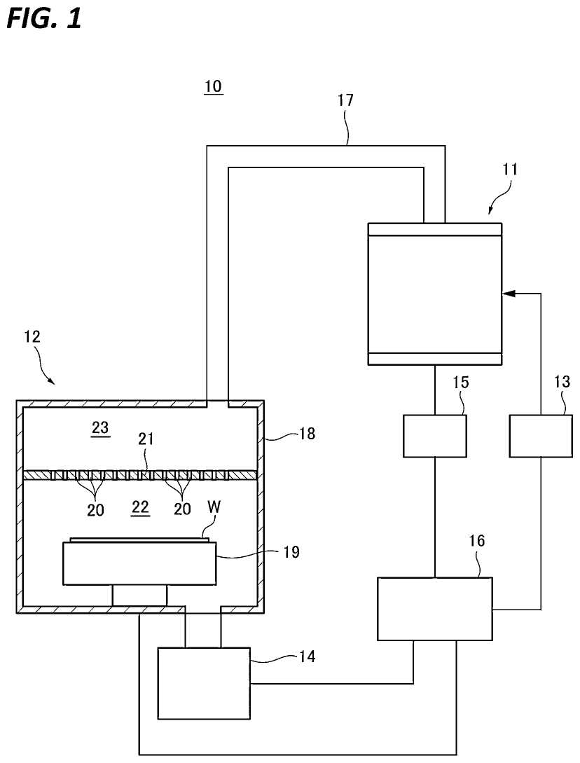

Hereinafter, an embodiment according to the present disclosure will be described with reference to the drawings. FIG. 1 is a diagram schematically illustrating the configuration of a semiconductor manufacturing system as an embodiment of the technology according to the present disclosure. In FIG. 1, the film forming apparatus is drawn as a cross-sectional view for ease of understanding.

In FIG. 1, a semiconductor manufacturing system 10 includes a vaporization device 11, a film forming apparatus 12, a carrier gas supply device 13, an exhaust device 14, a temperature control unit 15, and a control unit 16. The vaporization device 11 is connected to the film forming apparatus 12 via a gas supply path 17 and supplies a carrier gas containing a predetermined raw material to the film forming apparatus 12. The film forming apparatus 12 deposits the predetermined raw material on a wafer W (substrate) to form a predetermined thin film. A detailed configuration of the vaporization device 11 will be described later.

The film forming apparatus 12 includes a processing container 18 that accommodates the wafer W, a stage 19 arranged at the bottom of the processing container 18, and a vaporized raw material diffusion plate 21 having a plurality of through holes 20. The wafer W is placed on the stage 19. The vaporized raw material diffusion plate 21 partitions the inside of the processing container 18 into a processing chamber 22 where the stage 19 is present and a diffusion chamber 23. A gas supply path 17 is connected to the diffusion chamber 23, and a carrier gas is introduced from the vaporization device 11.

The introduced carrier gas is diffused in the diffusion chamber 23, passes through each through hole 20 of the vaporized raw material diffusion plate 21, and enters the processing chamber 22. A predetermined raw material contained in the carrier gas that has entered the processing chamber 22 is adsorbed onto the surface of the wafer W on the stage 19. A temperature control device (not illustrated) is built into the stage 19, and adjusts the temperature of the wafer W placed thereon. Specifically, the temperature control device increases the temperature of the wafer W to thermally decompose the predetermined raw materials adsorbed on the surface. At this time, a thin film, for example, a barrier layer is formed on the surface of wafer W, which is mainly composed of a predetermined raw material.

The carrier gas supply device 13 supplies, for example, carbon monoxide (CO) gas as the carrier gas to the vaporization device 11. The exhaust device 14 is constituted by, for example, a turbo-molecular pump, and decompresses the inside of the processing chamber 18 to a pressure suitable for the film formation process on the barrier layer. The temperature control unit 15 heats the entire vaporization device 11 and promotes vaporization of the predetermined raw material. The control unit 16 controls operations of the vaporization device 11, the film forming apparatus 12, the carrier gas supply device 13, the exhaust device 14, and the temperature control unit 15 to perform the film formation process.

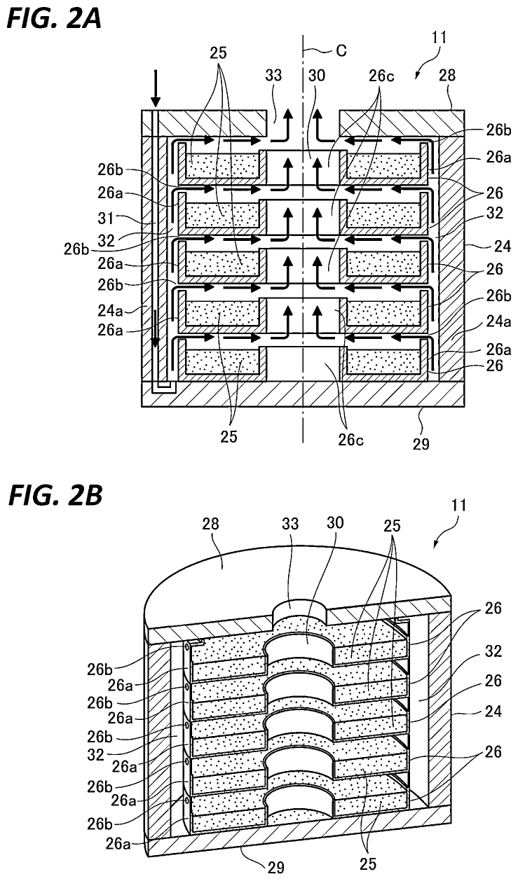

FIGS. 2A and 2B are diagrams illustrating the configuration of the vaporization device 11. FIG. 2A is a cross-sectional view of the vaporization device 11, and FIG. 2B is a perspective view illustrating the vaporization device 11 with a portion cut away.

In FIGS. 2A and 2B, the vaporization device 11 includes a cylindrical body 24, an upper lid 28 and a lower lid 29. The vaporization device 11 further includes a plurality of trays 26 which are ring-shaped containers each filled with a solid raw material containing Ru as a predetermined raw material, for example, DCR 25. The solid raw material filled in each tray 26 is not limited to DCR, and may be a precursor of a main component of the thin film formed by the film formation process.

Each tray 26 is accommodated inside the main body 24 and stacked in a direction of a central axis C of the main body 24 such that the central axis of each tray 26 coincides with the central axis C of the main body 24. Further, an opening 26c in the center of each tray 26 overlaps when viewed from above to form an exhaust passage 30 that penetrates the inside of the main body 24 from the bottom to the top. Since the opening 26c of each tray 26 is positioned on the central axis C of the main body 24, the exhaust passage 30 is formed along the central axis C. As a result, each tray 26 is arranged to surround the exhaust passage 30. Further, the upper lid 28 closes the upper opening of the main body 24, and the lower lid 29 closes the lower opening of the main body 24.

Heaters (not illustrated) (heating units) are built into a side wall 24a, the upper lid 28, and the lower lid 29 of the main body 24, and the control unit 16 controls each heater to heat the DCR 25 filled in each tray 26, thereby promoting the vaporization.

Further, a carrier gas passage 31 is formed inside the upper lid 28, the side wall 24a of the main body 24, and the lower lid 29, and the carrier gas passage 31 is connected to the carrier gas supply device 13 via piping (not illustrated). The carrier gas supplied from the carrier gas supply device 13 passes through the carrier gas passage 31 and is introduced into the main body 24.

The outer diameter of each tray 26 is set to be smaller than the inner diameter of the main body 24. Thus, a ring-shaped space 32 is formed between the side wall 24a of the main body 24 and an outer wall 26a of each tray 26. Further, a plurality of inlets 26b is opened in the outer wall 26a of each tray 26.

The carrier gas introduced into the main body 24 flows through the ring-shaped space 32, passes through each inlet 26b of each tray 26, and flows toward the exhaust passage 30. That is, the carrier gas is introduced from the lateral side of the main body 24 toward the exhaust passage 30 inside the main body 24.

When the carrier gas flows from each inlet 26b toward the exhaust passage 30, the carrier gas flows above the DCR 25 filled in the tray 26. At this time, the carrier gas entrains the vaporized DCR. When the carrier gas entrained with the vaporized DCR reaches the exhaust passage 30, the carrier gas flows upward along the exhaust passage 30, which is then exhausted from the vaporization device 11 through an exhaust port 33, and flows into the gas supply path 17. In FIG. 2A, the flow of the carrier gas is indicated by an arrow.

In the vaporization device of the related art having the same configuration as the vaporization device 11 except for the vaporization amount adjusting plate 35 described later, it has been confirmed that the formation efficiency of the barrier layer formed in the film formation process tends to decrease during the process.

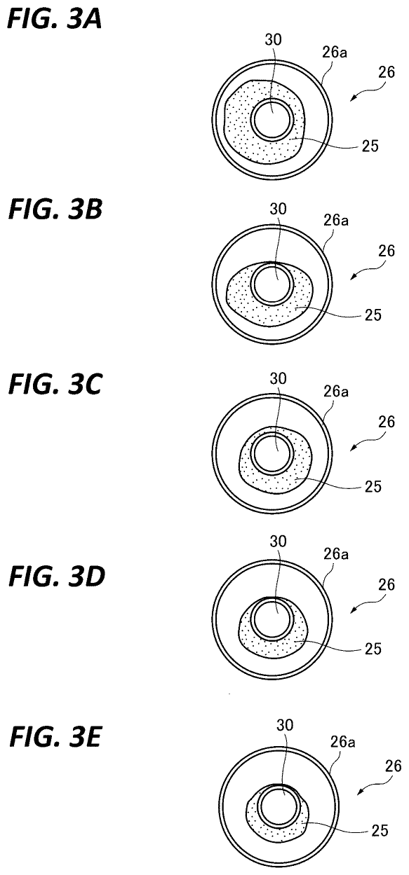

Therefore, the remaining form of the DCR 25 in each tray 26 has been confirmed after the formation efficiency of the barrier layer is lowered, and, as illustrated in FIGS. 3A to 3E, the DCR 25 remains biased toward the exhaust passage 30. FIG. 3A illustrates the remaining form of the DCR 25 in the uppermost tray 26, and FIG. 3B illustrates the remaining form of the DCR 25 in the second tray 26 from the top. Further, FIG. 3C illustrates the remaining form of the DCR 25 in the third tray 26 from the top, FIG. 3D illustrates the remaining form of the DCR 25 in the fourth tray 26 from the top, and FIG. 3E illustrates the remaining form of the DCR 25 in the lowest tray 26.

From the remaining form of the DCR 25 illustrated in FIGS. 3A to 3E, it can be seen that during the film formation process, for example, in each tray 26, vaporization is progressed from the DCR 25 on the side of the outer wall 26a, and the DCR 25 on the side of the outer wall 26a is entirely vaporized during the film formation process. For example, it has been found out that the bottom part of each tray 26 on the side of the outer wall 26a is exposed earlier than the bottom on the side of the exhaust passage 30.

Thus, the surface area of the DCR 25 exposed to the carrier gas in each tray 26 is reduced during the film formation process, the amount of vaporized DCR entrained by the carrier gas is reduced, and the partial pressure of the DCR in the carrier gas is lowered. As a result, it has been inferred that the amount of the DCR adsorbed onto the wafer W in the film forming apparatus 12 decreased, and the formation efficiency of the barrier layer decreased.

Therefore, in order to suppress the formation efficiency of the barrier layer from decreasing during the film formation process, it is necessary to suppress the progress of vaporization from the DCR 25 on the side of the outer wall 26a in each tray 26.

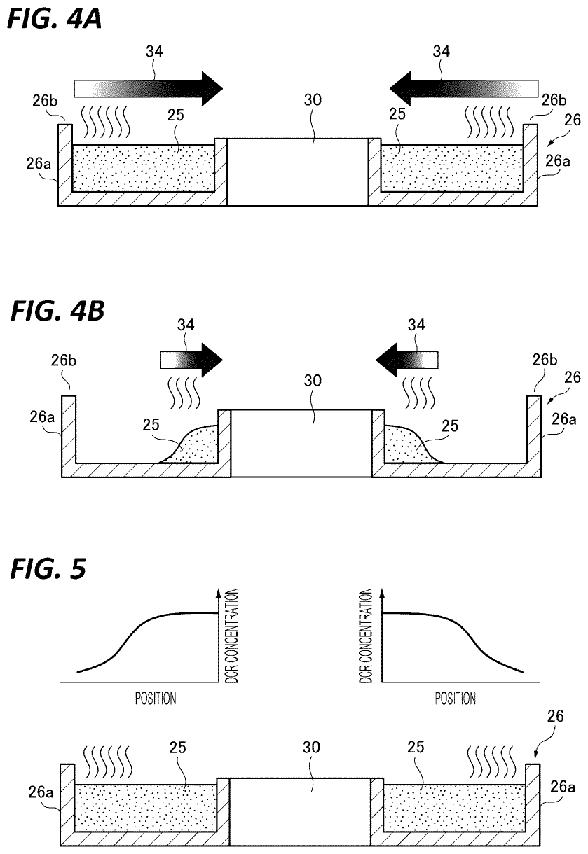

The present inventors have considered the reason why the vaporization progresses from the DCR 25 on the side of the outer wall 26a as illustrated in FIGS. 4A and 4B. In the present embodiment, hereinafter, the flow of the carrier gas 34 is represented by an arrow, and the brightness of the arrow represents the partial pressure of the DCR. The darker arrow indicates a higher partial pressure of the DCR in the carrier gas 34.

In the vaporization device 11, as the carrier gas 34 entrains the vaporized DCR 25 in each tray 26 when the carrier gas 34 flows from each inlet 26b of the outer wall 26a toward the outlet channel 30, a partial pressure of the DCR in the carrier gas 34 (hereinafter also referred to as a “concentration”) increases. Then, by the time the carrier gas 34 reaches the vicinity of the exhaust passage 30, the partial pressure of the DCR in the carrier gas 34 approaches the saturated vapor pressure of the DCR, and the vaporization of the DCR 25 in the vicinity of the exhaust passage 30 is suppressed (FIG. 4A).

As a result, the vaporization of the DCR 25 on the side of the outer wall 26a progresses relatively more than the DCR 25 near the exhaust passage 30, and even when the bottom of the tray 26 on the side of the outer wall 26a is exposed, the DCR 25 remains near the exhaust passage 30 (FIG. 4B).

Furthermore, the change in DCR concentration of the carrier gas 34 is calculated using a simulation model simulating the vaporizer 11. FIG. 5 is a diagram illustrating comparison of a graph indicating calculation results of the change in DCR concentration of the carrier gas 34 with a cross section of the tray 26. As illustrated in the graph in the figure, it is also confirmed that the DCR concentration of the carrier gas 34 reaches saturated vapor pressure while the carrier gas 34 reaches the exhaust passage 30 from the outer wall 26a.

The DCR concentration of the carrier gas 34 flowing through the exhaust passage 30 is also considered to increase toward the downstream side. As illustrated in FIGS. 3A to 3D, the remaining amount of the DCR 25 increases toward the upper stage of each stacked tray 26, that is, the downstream side of the carrier gas 34. From the above, it is also confirmed that when the DCR concentration of the carrier gas 34 increases, the vaporization of the DCR 25 is suppressed.

Therefore, in the embodiment, in order to suppress the progress of vaporization from the DCR 25 on the side of the outer wall 26a in each tray 26, the DCR concentration of the carrier gas 34 is prevented from reaching the saturated vapor pressure while the carrier gas 34 reaches the exhaust passage 30 from the outer wall 26a.

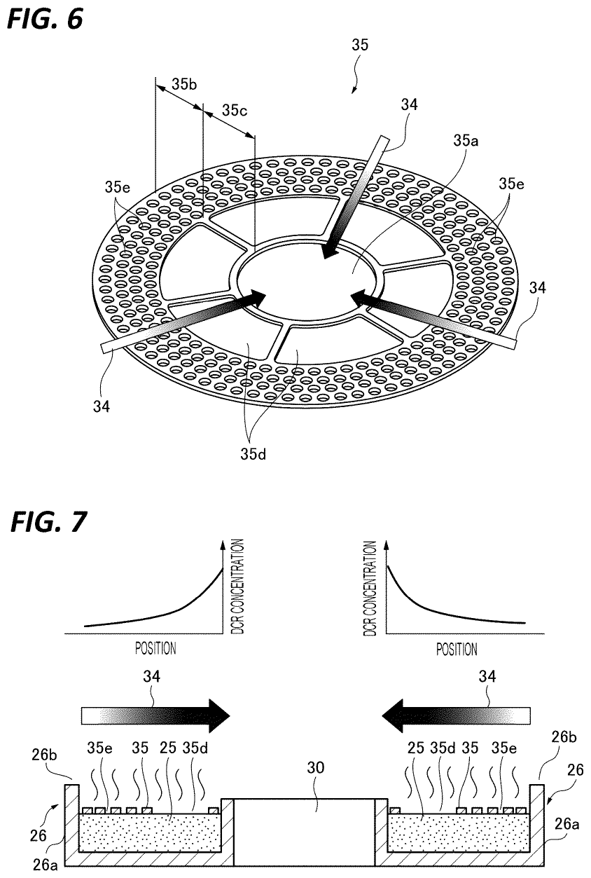

FIG. 6 is a perspective view illustrating the configuration of the vaporization amount adjusting plate 35 used in each tray 26 of the vaporization device 11.

The vaporization amount adjusting plate 35 is constituted by a disc-shaped member having a circular opening 35a corresponding to the exhaust passage 30 at the center, and is made of stainless steel or aluminum. Further, the shape of the vaporization amount adjusting plate 35 is not uniform, and the surface thereof is divided into an outer region 35b on the outer peripheral side and an inner region 35c on the center side. The inner region 35c surrounds the opening 35a and is set to be located closer to the exhaust passage 30 than the outer region 35b. Further, the outer region 35b is set to be located closer to the side wall 24a of the main body 24 than the inner region 35c.

In the vaporization amount adjusting plate 35, a plurality of inner vent holes 35d, which are relatively larger through holes, are formed in the inner region 35c so as to surround the opening 35a, and each inner vent hole 35d has a fan shape in plan view. Further, a plurality of outer vent holes 35e, which are circular through holes, are formed on the entire surface of the outer region 35b.

The number and size of each inner vent hole 35d and each outer vent hole 35e are set such that the aperture ratio per unit area in the inner region 35c is larger than the aperture ratio per unit area in the outer region 35b. For example, the aperture ratio per unit area of the vaporization amount adjusting plate 35 increases toward the exhaust passage 30. The aperture ratio as used herein is a ratio of the area occupied by each inner vent hole 35d and each outer vent hole 35e to the surface area of the vaporization amount adjusting plate 35. Further, the shape of each inner vent hole 35d is not limited to the fan shape in plan view, but may have other shapes. Also, the shape of each outer vent hole 35e is not limited to the circular shape, but may have another shape.

The vaporization amount adjusting plate 35 is arranged to fit into each tray 26 from above, and is placed directly on the DCR 25 to cover the surface of the DCR 25. At this time, in the tray 26, for example, the carrier gas 34 flows above the vaporization amount adjusting plate 35 from the outer wall 26a toward the exhaust passage 30, while facing the vaporization amount adjusting plate 35 (see, e.g., arrow in FIG. 6). Therefore, the aperture ratio per unit area of the vaporization amount adjusting plate 35 increases toward the downstream side in the flow of the carrier gas 34. The carrier gas 34 entrains and carries the DCR 25 that has vaporized and passed through each outer vent hole 35e and each inner vent hole 35d.

Here, since the aperture ratio per unit area in the outer region 35b is smaller than the aperture ratio per unit area in the inner region 35c, the amount of the DCR 25 that has vaporized and passed through each outer vent hole 35e is smaller than the amount of the DCR 25 that has vaporized and passed through each inner vent hole 35d. Therefore, the amount of DCR entrained when the carrier gas 34 passes above the vaporization adjusting plate 35 is also reduced, so that the concentration of the DCR may be prevented from reaching the saturated vapor pressure while the carrier gas 34 reaches the exhaust passage 30 from the outer wall 26a.

Further, the inventors used a simulation model simulating the vaporization device 11 to calculate the change in the DCR concentration of the carrier gas 34 when the vaporization amount adjusting plate 35 was placed directly on the DCR 25. FIG. 7 is a diagram illustrating comparison of a graph indicating calculation results of the change in DCR concentration of the carrier gas 34 when using the vaporization amount adjusting plate 35 with a cross section of the tray 26. As illustrated in the graph in the figure, it is found that the DCR concentration of the carrier gas 34 does not reach the saturated vapor pressure while the carrier gas 34 reaches the exhaust passage 30 from the outer wall 26a, and the carrier gas 34 reaches the exhaust passage 30, but finally rises to near saturated vapor pressure when the carrier gas 34 reaches the exhaust passage 30.

In the embodiment, by using the vaporization amount adjusting plate 35, it is possible to prevent the concentration of the DCR from reaching the saturated vapor pressure while the carrier gas 34 reaches the exhaust passage 30 from the outer wall 26a. As a result, it is possible to suppress the relative progress of the vaporization from the DCR 25 on side of the outer wall 26a without suppressing the vaporization of the DCR 25 on the side of the exhaust passage 30.

When the vaporization amount adjusting plate 35 is used, the bottom of each tray 26 on the side of the outer wall 26a is not exposed earlier than the bottom on the side of the exhaust passage 30 during the film formation process, and the surface area of the DCR 25 is reduced, thereby suppressing the vaporization amount of the DCR 25 from decreasing. Thus, it is possible to suppress the formation efficiency of the barrier layer formed in the film formation process from decreasing during the process.

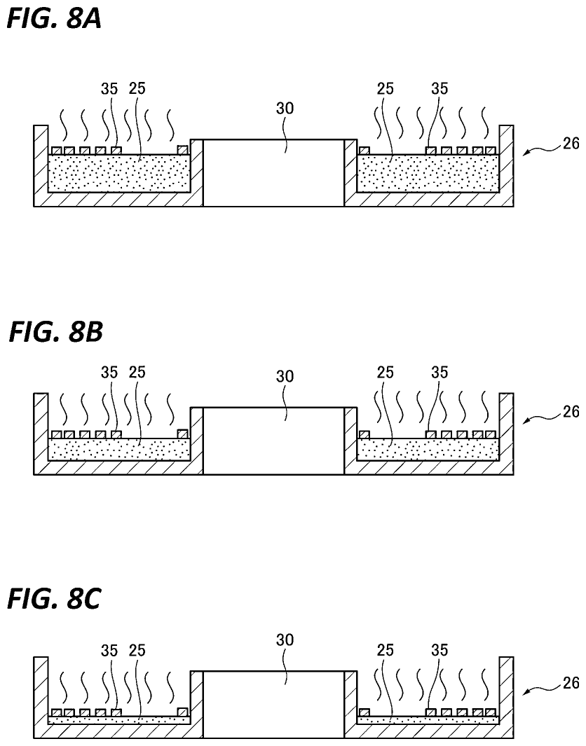

In the present embodiment, as described above, since vaporization does not proceed from the DCR 25 on the side of the outer wall 26a, the DCR 25 decreases almost evenly from the side of the outer wall 26a to the side of the exhaust passage 30. Further, the vaporization amount adjusting plate 35 is placed directly on the DCR 25. Therefore, as the vaporization of the DCR 25 progresses, the vaporization amount adjusting plate 35 descends in contact with the DCR 25 while maintaining a parallel position with the bottom of each tray 26 (see, e.g., FIGS. 8A to 8C).

At this time, even when the remaining DCR 25 is unevenly biased due to the vaporization of the DCR 25, the vaporization amount adjusting plate 35 presses the DCR 25 from above with its own weight, so that the DCR 25 is leveled, and the bias of the DCR 25 may be eliminated. Further, the vaporization amount adjusting plate 35 is indirectly heated by the heater of the vaporization device 11, but since the vaporization amount adjusting plate 35 contacts the DCR 25, it may assist in heating the DCR 25 and further promote the vaporization of the DCR 25.

Although embodiments of the present disclosure have been described above, the present disclosure is not limited to the embodiments described above, and various modifications and changes may be made within the scope of the gist.

For example, the vaporization amount adjusting plate 35 is divided into two regions (inner region 35c and outer region 35b) with different aperture ratios per unit area, but the vaporization amount adjusting plate 34 may be divided into three or more regions with different aperture ratios per unit area. However, in this case, the aperture ratio per unit area of each region is set to increase from the outer wall 26a toward the exhaust passage 30. Alternatively, the vaporization amount adjusting plate 35 may be provided with a plurality of vent holes (through holes) such that the change in the aperture ratio per unit area increases toward the exhaust passage 30, without the vaporization amount adjusting plate 35 being clearly divided into a plurality of regions.

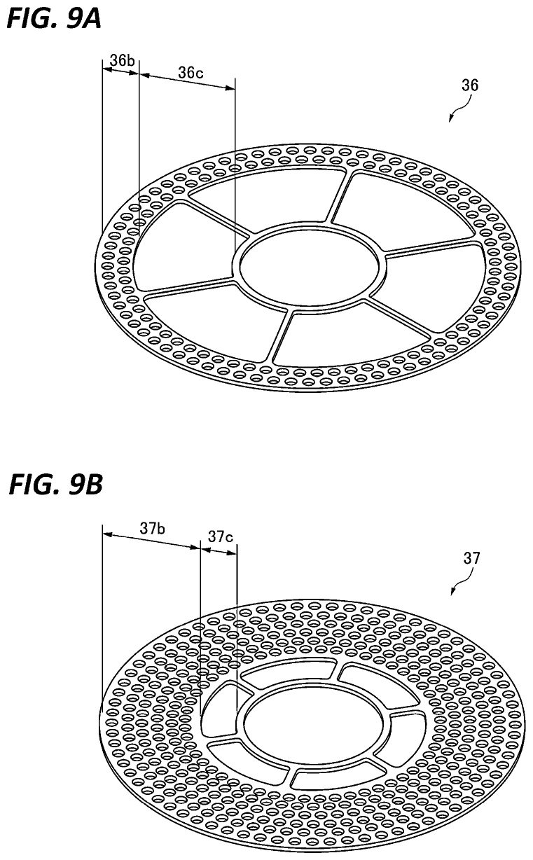

Further, even when the vaporization amount adjusting plate is divided into two regions having different aperture ratios per unit area, the ratio of the outer area to the inner area is not limited to the case of the vaporization amount adjusting plate 35 illustrated in FIG. 6. For example, depending on the remaining form of the DCR 25, a vaporization amount adjusting plate 36 may be used in which the outer region 36b is smaller than the outer region 35b of the vaporization amount adjusting plate 35, and the inner region 36c is larger than the inner region 35c of the vaporization amount adjusting plate 35 (see, e.g., FIG. 9A). Alternatively, a vaporization amount adjusting plate 37 may be used in which the outer region 37b is larger than the outer region 35b of the vaporization amount adjusting plate 35, and the inner region 37c is smaller than the inner region 35c of the vaporization amount adjusting plate 35 (see, e.g., FIG. 9B).

Furthermore, in each tray 26, vaporization amount adjusting plates having different overall aperture ratios may be used. For example, as described above, in the vaporization device 11, the remaining amount of the DCR 25 increases toward the upper stage of each stacked tray 26, that is, the downstream side of the carrier gas 34. Correspondingly, the overall aperture ratio of each vaporization amount adjusting plate may be set to become smaller toward the lower stage of each tray 26 corresponding to the upstream side of the carrier gas 34.

Thus, the amount of the DCR entrained in the upstream of the carrier gas 34 may be reduced, and the concentration of the DCR may be suppressed from reaching the saturated vapor pressure in the middle of the exhaust passage 30. As a result, it is possible to prevent the vaporization of the DCR 25 from being suppressed in the upper tray 26 corresponding to the downstream side of the carrier gas 34, and to prevent differences in the remaining amount of the DCR 25 in each tray 26.

As illustrated in FIGS. 9A and 9B, the entire aperture ratio of the vaporization amount adjusting plate 36 is larger than the entire aperture ratio of the vaporization amount adjusting plate 35, and the overall aperture ratio of the vaporization amount adjusting plate 37 is smaller than the entire aperture ratio of the vaporization amount adjusting plate 35. Therefore, in the film formation process, for example, the vaporization amount adjusting plate 37 (see, e.g., FIG. 9B) is used for the lower tray 26, the vaporization amount adjusting plate 35 (see, e.g., FIG. 6) is used for the middle tray 26, and the vaporization adjusting plate 36 (see, e.g., FIG. 9A) for the upper tray 26.

In any case, any vaporization amount adjusting plate in which the aperture ratio per unit area is set to be larger toward the downstream of the carrier gas 34 corresponds to an embodiment of the technology according to the present disclosure.

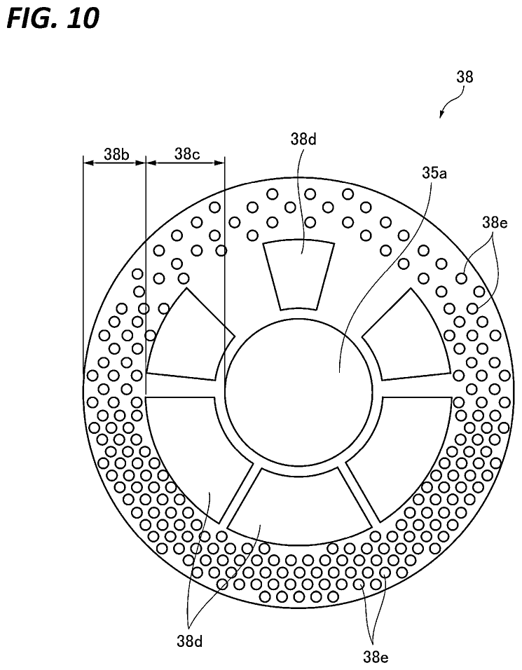

Further, as illustrated in FIGS. 3A to 3E, in each tray 26, the remaining shape of the DCR 25 is not uniform in the circumferential direction, and a biasing of the DCR 25 occurs. Therefore, the aperture ratio of the vaporization amount adjusting plate may be changed in the circumferential direction. For example, as in the vaporization amount adjusting plate 38 illustrated in FIG. 10, in the inner region 38c, the inner vent hole 38d is made larger at locations where there is a large amount of remaining DCR 25, and the inner vent hole 38d is made smaller at locations where there is a small amount of remaining DCR 25, with respect to the circumferential direction. Further, in the outer region 38b, the number of outer vent holes 38e is increased at locations where there is a large amount of remaining DCR 25, and the number of outer vent holes 38e is decreased at locations where there is a small amount of remaining DCR 25, with respect to the circumferential direction.

In the embodiment described above, when performing the film formation process, the vaporization amount adjusting plate 35 is placed directly on the DCR 25 in each tray 26. However, by providing a protrusion on the outer wall 26a and engaging the vaporization amount adjusting plate 35 with the protrusion, the film formation process may be performed while the vaporization amount adjusting plate 35 and the DCR 25 are separated from each other.

According to the technology described in the present disclosure, the formation efficiency of layers formed using thermal decomposition of solid raw materials may be reduced during the process.

From the foregoing, it will be appreciated that various embodiments of the present disclosure have been described herein for purposes of illustration, and that various Modifications may be made without departing from the scope and spirit of the present disclosure. Accordingly, the various embodiments disclosed herein are not intended to be limiting, with the true scope and spirit being indicated by the following claims.

What is claimed is:

1. A vaporization device comprising:
a vaporization amount adjusting plate configured to cover a surface of a solid raw material; and
an exhaust passage configured to exhaust a carrier gas that flows while being faced with the vaporization amount adjusting plate,
wherein the vaporization amount adjusting plate has a plurality of through holes,
an aperture ratio per unit area in the vaporization amount adjusting plate varies along a flowing direction of the carrier gas, and
the carrier gas is vaporized from the solid raw material and carries a predetermined raw material that has passed through the plurality of through holes.

2. The vaporization device according to claim 1, wherein the aperture ratio per unit area in the vaporization amount adjusting plate increases toward a downstream side of a flow of the carrier gas.

3. The vaporization device according to claim 1, wherein the aperture ratio per unit area in the vaporization amount adjusting plate increases toward the exhaust passage.

4. The vaporization device according to claim 3, further comprising:
a body in a tubular shape; and
a tray configured to be filled with the solid raw material,
wherein the vaporization amount adjusting plate is disposed in the tray to cover the surface of the solid raw material,
the exhaust passage is formed along a central axis of the body, and
the carrier gas is introduced from a lateral side of the body toward an interior of the body.

5. The vaporization device according to claim 4, wherein the vaporization amount adjusting plate has at least an outer region closer to an outer wall of the body and an inner region closer to the exhaust passage than the outer region, and
an aperture ratio per unit area in the inner region is larger than an aperture ratio per unit area in the outer region.

6. The vaporization device according to claim 5, wherein the body has a cylindrical shape,
the tray is constituted by a ring-shaped container surrounding the exhaust passage, and
each through hole in the inner region has a fan shape in plan view.

7. The vaporization device according to claim 5, wherein the body has a cylindrical shape,
the tray is constituted by a ring-shaped container surrounding the exhaust passage, and
the aperture ratio per unit area in the vaporization amount adjusting plate further varies with respect to a circumferential direction of the tray.

8. The vaporization device according to claim 4, wherein a plurality of trays are arranged inside the body to be stacked in a direction of the central axis of the body, and
the aperture ratio of each of the vaporization amount adjusting plates arranged on each of the trays increases toward a downstream side of the exhaust passage.

9. The vaporization device according to claim 1, wherein the vaporization amount adjusting plate is made of stainless steel or aluminum.

10. The vaporization device according to claim 1, wherein the vaporization amount adjusting plate is placed directly on the solid raw material.

11. The vaporization device according to claim 1, further comprising
a heater configured to heat the solid raw material.

12. A semiconductor manufacturing system comprising:
a vaporization device configured to vaporize a predetermined material from a solid raw material; and
a film forming apparatus configured to deposit the predetermined material vaporized by the vaporization device, thereby forming a film on a substrate,
wherein the vaporization device includes:
a vaporization amount adjusting plate configured to cover a surface of a solid raw material; and
an exhaust passage configured to exhaust a carrier gas that flows while being faced with the vaporization amount adjusting plate,
wherein the vaporization amount adjusting plate has a plurality of through holes,
an aperture ratio per unit area in the vaporization amount adjusting plate varies along a flowing direction of the carrier gas, and
the carrier gas is vaporized from the solid raw material and carries a predetermined raw material that has passed through the plurality of through holes.

13. A method of vaporizing a solid raw material, the method comprising:
providing a vaporization device including a vaporization amount adjusting plate that covers a surface of the solid raw material, the vaporization amount adjusting plate having a plurality of through holes, and an aperture ratio per unit area in the vaporization amount adjusting plate varying along a flowing direction of a carrier gas carrying a predetermined material vaporized from the solid raw material;
covering the surface of the solid raw material with the vaporization amount adjusting plate;
causing the carrier gas to flow while being faced with the vaporization amount adjusting plate; and
carrying, by the carrier gas, the predetermined material that has been vaporized from the solid raw material and has passed through the plurality of through holes.

14. The method according to claim 13, wherein the vaporization amount adjusting plate is placed directly on the solid raw material, and
the vaporization amount adjusting plate is lowered as vaporization of the solid raw material progresses.

15. The method according to claim 13, further comprising heating the solid raw material.
